(19) United States
(12) Patent Application Publication
(10) Pub. No.: US 2025/0323040 A1
(43) Pub. Date: Oct. 16, 2025

(54) METHODS FOR BONDING SEMICONDUCTOR SUBSTRATES

(71) Applicant: Applied Materials, Inc., Santa Clara, CA (US)

(72) Inventor: Yoocharn JEON, Palo Alto, CA (US)

(21) Appl. No.: 18/631,810

(22) Filed: Apr. 10, 2024

(51) Int. Cl. H01L 21/20; H01L 21/02; H01L 21/324

(52) U.S. Cl. CPC H01L 21/2007; H01L 21/02164; H01L 21/02178; H01L 21/324

(57) ABSTRACT

Methods for preparing a substrate and bonding two substrates together which include a bonding layer disposed directly over and in contact with a barrier layer in which the bonding layer has a higher water diffusivity than the barrier layer. A substrate and a bonded pair of substrates is also disclosed.

### FIELD

Embodiments of the present disclosure generally relate to methods for bonding semiconductor substrates together, and bonded semiconductor substrates.

### BACKGROUND

Formation of semiconductor devices may include two or more semiconductor wafers or dies, referred to collectively herein as semiconductor substrates, which are stacked relative to one another in a face-to-face, back to back, or face to back configuration, and bonded together. Such bonded semiconductor devices typically include conductive members providing electrical communication between the bonded substrates. Wafer or die bonding is achieved by forming chemical bonds between two opposing bonding surfaces at the bonding interface. However, the inventors have observed weak bonding between two bonded surfaces.

Accordingly, the inventors have provided embodiments of improved methods of bonding semiconductor substrates.

### SUMMARY

Methods for bonding semiconductor substrates are provided herein, along with semiconductor devices comprising bonded substrates. In some embodiments, a method of preparing a first substrate for bonding with a second substrate comprises depositing a first barrier layer of a first dielectric material on a dielectric layer of the first substrate; and depositing a first bonding layer of a second dielectric material on the first barrier layer; wherein the second dielectric material has a higher water diffusivity than the first dielectric material.

In some embodiments, a method of forming a semiconductor device, comprises forming a first dielectric layer on a surface of a first semiconductor substrate; forming a first barrier layer on a surface of the first dielectric layer; forming a first bonding layer on a surface of the first barrier layer; wherein the first bonding layer has a higher water diffusivity than the first barrier layer; and wherein a thickness of the first bonding layer is less than or equal to about 100 nm.

In embodiments, a semiconductor device comprises a first substrate comprising a first dielectric bonding layer having a lower surface disposed over, and in contact with an upper surface of a first dielectric barrier layer, wherein the first dielectric bonding layer has a higher water diffusivity than the first dielectric barrier layer; and wherein a thickness of the first dielectric bonding layer is less than or equal to about 100 nm.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a substrate prepared for bonding according to embodiments disclosed herein.

FIG. 2 depicts a semiconductor device having a bonded pair semiconductor devices according to embodiments disclosed herein.

FIG. 3 depicts a semiconductor device having a bonded pair of semiconductor devices having substrates next to a bonded metal layers according to embodiments disclosed herein.

FIG. 4 is a flowchart depicting a method of preparing a first substrate for bonding with a second substrate according to embodiments disclosed herein.

FIG. 5 is a flowchart of a method of preparing a first substrate for bonding with a second substrate according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

As used herein, the term “semiconductor substrate” is used synonymously with the truncated term “substrate”, and also with the terms “wafers”, “dies”, and the like, unless otherwise indicated. Silicon oxides, also referred to herein as “a silicon oxide”, refers to materials having the general formula SiOₓ, wherein x is greater than or equal to 1 to render a neutral molecule. Silicon nitrides, also referred to herein as “a silicon nitride”, refers to materials having the general formula SiₓNy wherein x is greater than or equal to 1 and y is greater than or equal to 1 to render a neutral molecule. Silicon oxynitrides, also referred to herein as “a silicon oxynitride”, refers to materials having the general formula SiOₓNy, wherein x+y is greater than or equal to 1 to render a neutral molecule. Aluminum oxides, also referred to herein as “an aluminum oxide”, refers to materials having the general formula AlₓO_{y}, wherein x is greater than or equal to 1 and y is greater than or equal to 1 to render a neutral molecule. Titanium oxides, also referred to herein as “a titanium oxide”, refers to materials having the general formula TiOₓ, wherein x is greater than or equal to 1 to render a neutral molecule. Hafnium oxides, also referred to herein as “a hafnium oxide”, refers to materials having the general formula HfOₓ, wherein x is greater than or equal to 1 to render a neutral molecule. Tantalum oxides, also referred to herein as “a tantalum oxide”, refers to materials having the general formula TaₓO_{y}, wherein x is greater than or equal to 1 and y is greater than or equal to 1 to render a neutral molecule. Silicon carbonitride refers to materials having the empirical formula Si₍ₓ₎C(1−x) Ny, wherein x+y+z is greater than or equal to 1 to render a neutral molecule, and silicon oxycarbonitride refers to materials having the empirical formula Si₍ₓ₎C(1−x) O_{y}N_{z} wherein x+y+z is greater than or equal to 1 to render a neutral molecule.

In embodiments, a semiconductor substrate comprises bonded wafers/dies having a bonding dielectric interface wherein two separate semiconductor substrates are bonded to each other through a bonding layer to form a single semiconductor substrate, wherein barrier layers are disposed under, and contacting each of the bonding layers.

Methods of manufacturing a semiconductor device according to embodiments disclosed herein comprise contacting a bonding surface of a bonding layer of each of two substrates with each other, wherein each of the two substrates have a barrier layer directly under and in contact with the bonding layer. In embodiments, after putting the two bonding layers of the two substrates in contact, the substrates are heated at an elevated temperature, also referred to herein as annealing, to further strengthen the bond between the two bonding layers forming a single bonding layer disposed between the two barrier layers.

The inventors have observed that wafer/die bonding is mainly achieved by forming chemical bonds between two bonding surfaces, which for example may comprise a silicon oxide, e.g., SiO₂. The inventors have further observed that bonding of the two surfaces is facilitated by water molecules at the bonding interface. The water molecules have been observed to diffuse through the bonding materials during the bond anneal, and are removed from the bonding interface before the whole interface is bonded, resulting in a weaker bond between the two substrates. The inventors have observed that a barrier layer disposed under the bonding layers keep water molecules longer at the interface, which increases the bond strength between two bonded substrates.

In embodiments, a method of preparing a first substrate for bonding with a second substrate comprises depositing a first barrier layer of a first dielectric material on a dielectric layer of the first substrate; and depositing a first bonding layer of a second dielectric material on the first barrier layer, wherein the second dielectric material has a higher water diffusivity than the first dielectric material.

In embodiments, a thickness of the first bonding layer is less than or equal to about 100 nm. In embodiments, a thickness of the first barrier layer is less than or equal to about 100 nm. In embodiments, the thickness of at least one of the first bonding layer or the second bonding layer is less than or equal to about 10 nm. In embodiments, the thickness of at least one of the first bonding layer or the second bonding layer is less than or equal to about 5 nm, or less than or equal to about 3 nm.

In embodiments, the second dielectric material comprises a silicon oxide, a silicon nitride, a silicon oxynitride, silicon carbonitride, silicon oxycarbonitride, or a combination thereof. In embodiments, the second dielectric material consists essentially of a silicon oxide. In embodiments, the first dielectric material comprises an aluminum oxide, a titanium oxide, a hafnium oxide, a tantalum oxide, silicon carbonitride, or a combination thereof. In embodiments, the first dielectric material consists essentially of an aluminum oxide.

In some embodiments, the method further comprises contacting the first bonding layer of the first substrate with a corresponding first bonding layer of the second substrate under conditions sufficient to bond the first bonding layer of the first substrate to the first bonding layer of the second substrate. In embodiments, the first bonding layer of the first substrate is bonded to the first bonding layer of the second substrate with a bond strength of greater than or equal to about 2 J/m². In embodiments, the conditions sufficient to bond the first bonding layer of the first substrate to the first bonding layer of the second substrate comprise annealing at a temperature from about 300° C. to about 400° C. for a period of time greater than or equal to about 30 min.

In embodiments, the first barrier layer is deposited next to and in contact with at least one metal layer, and the first bonding layer is deposited on the first barrier layer next to and in contact with the same one or more metal layers, such that an upper surface of the one or more metal layers and an upper surface of the first bonding layer form a hybrid bonding surface. In embodiments, the method further comprises contacting the hybrid bonding surface of the first substrate with a corresponding hybrid bonding surface of a second substrate such that the first bonding layer and the at least one metal layer of the first substrate each contact a corresponding first bonding layer and at least one metal layer of the second substrate under conditions sufficient to bond the first bonding layer of the first substrate to the first bonding layer of the second substrate.

In embodiments, a method of forming a semiconductor device comprises forming a first dielectric layer on a surface of a first semiconductor substrate; forming a first barrier layer on a surface of the first dielectric layer; forming a first bonding layer on a surface of the first barrier layer; wherein the first bonding layer has a higher water diffusivity than the first barrier layer; and wherein a thickness of the first bonding layer is less than or equal to about 100 nm.

In embodiments, the first dielectric layer, the first barrier layer and the first bonding layer are formed next to a first metal layer disposed on a surface of the substrate, such that an upper surface of the first metal layer and an upper surface of the first bonding layer form a first hybrid bonding surface. In embodiments, the method further comprises forming a second dielectric layer on a surface of a second semiconductor substrate; forming a second barrier layer on a surface of the second dielectric layer; forming a second bonding layer on a surface of the second barrier layer; and contacting a surface of the first bonding layer with a surface of the second bonding layer under conditions sufficient to bond the first bonding layer to the second bonding layer; wherein the second bonding layer has a higher water diffusivity than the second barrier layer; and wherein a thickness of the second bonding layer is less than or equal to about 100 nm; wherein the conditions sufficient to bond the first bonding layer to the second bonding layer comprise annealing at a temperature from about 300° C. to about 400° C. for a period of time greater than or equal to about 30 min.

In embodiments, the first dielectric layer, the first barrier layer and the first bonding layer are formed next to a first metal layer disposed on a surface of the substrate, such that an upper surface of the first metal layer and an upper surface of the first bonding layer form a first hybrid bonding surface; wherein the second dielectric layer, the second barrier layer and the second bonding layer are formed next to a second metal layer disposed on a surface of the second substrate such that an upper surface of the second metal layer and an upper surface of the second bonding layer form a second hybrid bonding surface; and contacting the first hybrid bonding surface with the second hybrid bonding surface under conditions sufficient to bond the first bonding layer to the second bonding layer, wherein the conditions sufficient to bond the first bonding layer to the second bonding layer comprise annealing at a temperature from about 300° C. to about 400° C. for a period of time greater than or equal to about 30 min.

In embodiments, a thickness of at least one of the first barrier layer or the second barrier layer is less than or equal to about 30 nm, or less than or equal to about 10 nm, or less than or equal to about 5 nm.

In embodiments, the first bonding layer is bonded to the second bonding layer with a bond strength of greater than or equal to about 2 J/m², or greater than or equal to about 3 J/m², or greater than or equal to about 3.5 J/m².

In embodiments, each bonding layer individually comprises a silicon oxide, a silicon nitride, a silicon oxynitride, silicon carbonitride, silicon oxycarbonitride, or a combination thereof; and/or wherein each barrier layer individually comprises an aluminum oxide, a titanium oxide, a hafnium oxide, a tantalum oxide, silicon carbonitride, or a combination thereof.

In embodiments, a semiconductor device comprises a first substrate comprising a first dielectric bonding layer having a lower surface disposed over, and in contact with an upper surface of a first dielectric barrier layer, wherein the first dielectric bonding layer has a higher water diffusivity than the first dielectric barrier layer; and wherein a thickness of the first dielectric bonding layer is less than or equal to about 100 nm.

In embodiments, the first substrate further comprises a first metal layer disposed thereon next to the first dielectric bonding layer. In embodiments, the semiconductor device further comprises a second substrate comprising a second dielectric bonding layer having a lower surface disposed over, and in contact with an upper surface of a second dielectric barrier layer; wherein an upper surface of the first dielectric bonding layer is bonded to an upper surface of the second dielectric bonding layer; wherein the second dielectric bonding layer has a higher water diffusivity than the second dielectric barrier layer; and wherein a thickness of the second dielectric bonding layer is less than or equal to about 100 nm.

In embodiments, each bonding layer individually comprises a silicon oxide, which in embodiments includes SiO₂, a silicon nitride, which in embodiments includes Si₃N₄, a silicon oxynitride, which in embodiments includes Si₂ON₂, silicon carbonitride, silicon oxycarbonitride, or a combination thereof. In embodiments, the composition of both bonding layers is essentially identical. In other embodiments, the composition of one bonding layer differs from the composition of the other bonding layer.

In embodiments, the thickness of both bonding layers is essentially identical. In other embodiments, the thickness of one bonding layer differs from the thickness of the other bonding layer.

In embodiments, the first and the second barrier layers consist essentially of an aluminum oxide, which in embodiments, is Al₂O₃.

In embodiments, each barrier layer individually comprises an aluminum oxide, which in embodiments includes Al₂O₃, a titanium oxide, which in embodiments includes TiO₂, a hafnium oxide, which in embodiments includes HfO₂, a tantalum oxide, which in embodiments includes Ta₂O₅, silicon carbonitride, or a combination thereof. In embodiments, each barrier layer consists essentially of an aluminum oxide.

In embodiments, the first bonding layer and the second bonding layer consist essentially of a silicon oxide, which in embodiments is SiO₂, and the first and the second barrier layers consist essentially of an aluminum oxide, which in embodiments, is Al₂O₃.

In embodiments, the substrates are contacted and subsequently heated to bond the substrates together. In embodiments, the conditions sufficient to bond the first bonding layer to the second bonding layer comprise annealing at a temperature of greater than or equal to about 300° C., and less than or equal to about 500° C., or from about 300° C. to about 400° C. for a period of time greater than or equal to about 30 min, or greater than or equal to about 60 min, or greater than or equal to about 120 min.

In embodiments, a method of forming a semiconductor device comprises forming a first dielectric layer on a surface of a first semiconductor substrate. The first dielectric layer may be formed by PVD, CVD, ALD, or any combination thereof. Next, a first barrier layer is formed on a surface of the first dielectric layer. The barrier layer may be formed by PVD, CVD, ALD, or any combination thereof. Next, a first bonding layer is formed on a surface of the first barrier layer, which again may be formed by PVD, CVD, ALD, or any combination thereof.

A second substrate is likewise prepared, either separately or at the same time as the first substrate, e.g., forming a second dielectric layer on a surface of a second semiconductor substrate; forming a second barrier layer on a surface of the second dielectric layer; and forming a second bonding layer on a surface of the second barrier layer.

The composition of the bonding layers and the composition of the barrier layers are independently selected such that the bonding layers have a higher water diffusivity than the barrier layer in contact with the bonding layer.

In embodiments, one or more of the bonding layers may comprise at least some of the same components present in the barrier layer so long as the water diffusivity of the bonding layer is higher than the water diffusivity of the barrier layer over which the bonding layer is disposed. For example, both a bonding layer and a corresponding barrier layer of a substrate may comprise silicon carbonitride so long as the water diffusivity of the bonding layer is higher than the water diffusivity of the barrier layer over which the bonding layer is disposed.

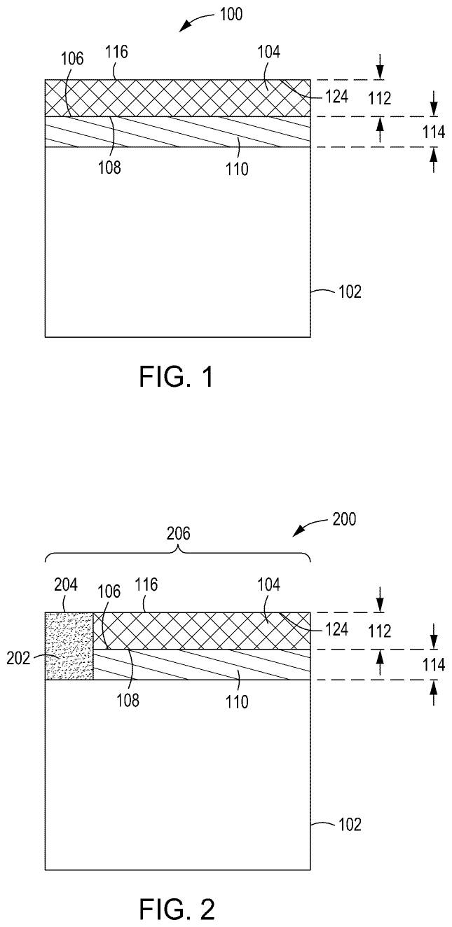

As shown in FIG. 1, in embodiments, a semiconductor device 100 comprises a first substrate 102 comprising a first dielectric bonding layer 104 having an upper bonding surface 116 suitable for bonding with another corresponding bonding layer, and a lower surface 106 disposed over, and in contact with an upper surface 108 of a first dielectric barrier layer 110, wherein the first dielectric bonding layer 104 has a higher water diffusivity than the first dielectric barrier layer 110; and wherein a thickness 112 of the first dielectric bonding layer 104 is less than or equal to about 100 nm. In embodiments, a thickness 114 of the first dielectric barrier layer 110 is less than or equal to about 100 nm.

As shown in FIG. 2, in embodiments, a hybrid substrate 200 includes the first dielectric barrier layer 110 deposited next to and in contact with at least one metal layer 202, and the first dielectric bonding layer 104 is deposited on the first dielectric barrier layer 110 next to and in contact with the same at least one metal layer 202, such that an upper surface 204 of the at least one metal layer 202, combined with the upper bonding surface 116 of the first dielectric bonding layer 104, forms a hybrid bonding surface 206.

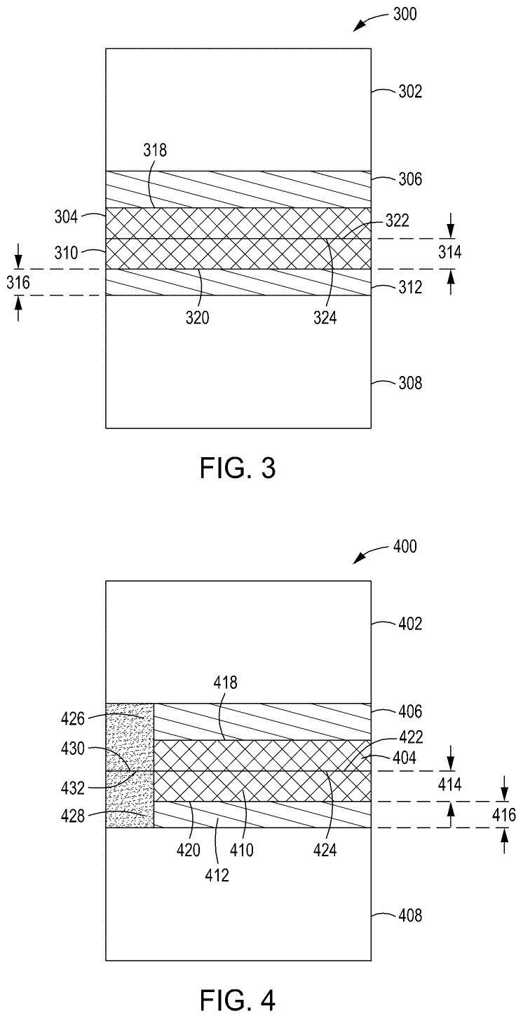

As shown in FIG. 3, a bonded pair of semiconductor device (300) comprises a first substrate 302 comprising a first bonding layer 304 having an upper surface 318 in contact with a first barrier layer 306, a corresponding second substrate 308 comprising a second bonding layer 310 having a lower surface 320 in contact with (i.e., disposed over and in contact with) a second barrier layer 312. A lower surface 322 of the first bonding layer 304 is bonded to an upper surface 324 of the second bonding layer 310. The first bonding layer 304 has a higher water diffusivity than the first barrier layer 306 and the second bonding layer 310 has a higher water diffusivity than the second barrier layer 312. In embodiments, a thickness 314 of each bonding layer is less than or equal to about 100 nm. In embodiments, a thickness 316 of each barrier layer is less than or equal to about 100 nm.

In embodiments, the first bonding layer 304 is bonded to the second bonding layer 310 with a bond strength of greater than or equal to about 2 J/m². In embodiments, the first and second bonding layers form an essentially continuous and uniform layer such that no seam exists at the bonding interface, i.e., the intersection of the lower surface 322 of the first bonding layer 304 and the upper surface 324 of the second bonding layer 310.

As shown in FIG. 4, In embodiments, a bonded pair semiconductor device (400) comprises a first substrate 402 comprising a first bonding layer 404 proximate or next to a first metal layer 426, the first bonding layer 404 having an upper surface 418 in contact with a first barrier layer 406. The first bonding layer 404 and the first metal layer 426 together forming a hybrid bonding layer. A second substrate 408 comprising a second bonding layer 410 proximate to a second metal layer 428, the second bonding layer 410 having a lower surface 420 in contact with (i.e., disposed over and in contact with) a second barrier layer 412. The second bonding layer 410 and the second metal layer 428 together forming a hybrid bonding layer. A lower surface 422 of the first bonding layer 404 is bonded to an upper surface 424 of the second bonding layer 410 and a lower surface 430 of the first metal layer 426 is bonded to an upper surface 432 of the second metal layer 428 forming a hybrid bonding layer through a hybrid bonding process. The first bonding layer 404 has a higher water diffusivity than the first barrier layer 406 and the second bonding layer 4 has a higher water diffusivity than the second barrier layer. While FIG. 2 shows a single metal layer or contact proximate to a dielectric bonding layer, it is to be understood that a substrate may include a plurality of both metal layers and dielectric layers.

In embodiments, a thickness 414 of each bonding layer is less than or equal to about 100 nm, or less than or equal to about 10 nm, or less than or equal to about 3 nm. In embodiments, a thickness 416 of each barrier layer is less than or equal to about 100 nm, or less than or equal to about 10 nm, or less than or equal to about 3 nm.

In embodiments, the first bonding layer 404 is bonded to the second bonding layer 410 with a bond strength of greater than or equal to about 2 J/m². In embodiments, the first and second bonding layers 404 and 410, and the first and second metal layers 426 and 428, form an essentially continuous and uniform layer such that no seam exists at the bonding interface, i.e., the intersection of the lower surface 422 of the first bonding layer 404 and the upper surface 424 of the second bonding layer 410, and the intersection of the lower surface 430 of the first metal layer 426 and the upper surface 432 of the second metal layer 428.

Without wishing to be bound by theory, the inventors believe that the bonding strength between the two bonding layers is improved by keeping water molecules present in the two layers for a longer time during the anneal. In embodiments, a barrier layer is arranged above and below two bonding layers to retain the water longer during the anneal.

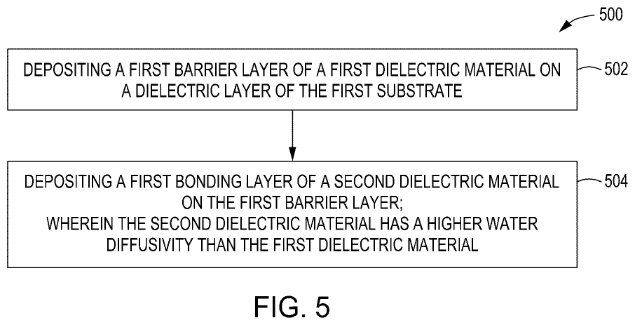

FIG. 5 is a flowchart of a method 500 of preparing a first substrate for bonding with a second substrate, comprising depositing a first barrier layer of a first dielectric material on a dielectric layer of the first substrate (block 502); and depositing a first bonding layer of a second dielectric material on the first barrier layer; wherein the second dielectric material has a higher water diffusivity than the first dielectric material (block 504), according to embodiments disclosed herein. In some embodiments, blocks 502 and 504 may be embodied in instructions on a controller that can control processing equipment to perform the method.

Although FIG. 5 shows exemplary blocks of method 500, in some implementations, method 500 may include additional blocks.

### Embodiments According to the Instant Disclosure Include:

E1. A method of preparing a first substrate for bonding with a second substrate, comprising:
   depositing a first barrier layer of a first dielectric material on a dielectric layer of the first substrate; and
   depositing a first bonding layer of a second dielectric material on the first barrier layer;
   wherein the second dielectric material has a higher water diffusivity than the first dielectric material.
E2. The method according to Embodiment E1, wherein a thickness of the first bonding layer is less than or equal to about 100 nm.
E3. The method according to Embodiments E1-E2, wherein a thickness of the first barrier layer is less than or equal to about 100 nm.
E4. The method according to Embodiments E1-E3, wherein the second dielectric material comprises a silicon oxide, a silicon nitride, a silicon oxynitride, silicon carbonitride, silicon oxycarbonitride, or a combination thereof.
E5. The method according to Embodiments E1-E4, wherein the second dielectric material consists essentially of a silicon oxide.
E6. The method according to Embodiments E1-E5, wherein the first dielectric material comprises an aluminum oxide, a titanium oxide, a hafnium oxide, a tantalum oxide, silicon carbonitride, or a combination thereof.
E7. The method according to Embodiments E1-E6, wherein the first dielectric material consists essentially of an aluminum oxide.
E8. The method according to Embodiments E1-E7, further comprising contacting the first bonding layer of the first substrate with a corresponding first bonding layer of the second substrate under conditions sufficient to bond the first bonding layer of the first substrate to the first bonding layer of the second substrate.
E9. The method according to Embodiment E8, wherein the first bonding layer of the first substrate is bonded to the first bonding layer of the second substrate with a bond strength of greater than or equal to about 2 J/m².
E10. The method according to Embodiments E8-E9, wherein the conditions sufficient to bond the first bonding layer of the first substrate to the first bonding layer of the second substrate comprise annealing at a temperature from about 300° C. to about 400° C. for a period of time greater than or equal to about 30 min.
E11. The method according to Embodiments E1-E10, wherein the first barrier layer is deposited next to and in contact with at least one metal layer, and the first bonding layer is deposited on the first barrier layer next to and in contact with the same one or more metal layers, such that an upper surface of the one or more metal layers and an upper surface of the first bonding layer form a hybrid bonding surface.
E12. The method according to Embodiments E1-E11, further comprising contacting the hybrid bonding surface of the first substrate with a corresponding hybrid bonding surface of a second substrate such that the first bonding layer and the at least one metal layer of the first substrate each contact a corresponding first bonding layer and at least one metal layer of the second substrate under conditions sufficient to bond the first bonding layer of the first substrate to the first bonding layer of the second substrate.
E13. A method of forming a semiconductor device, comprising:
   forming a first dielectric layer on a surface of a first semiconductor substrate; forming a first barrier layer on a surface of the first dielectric layer; forming a first bonding layer on a surface of the first barrier layer;
   wherein the first bonding layer has a higher water diffusivity than the first barrier layer; and
   wherein a thickness of the first bonding layer is less than or equal to about 100 nm.
E14. The method according to Embodiment E13, wherein the first dielectric layer, the first barrier layer and the first bonding layer are formed next to a first metal layer disposed on a surface of the substrate, such that an upper surface of the first metal layer and an upper surface of the first bonding layer form a first hybrid bonding surface.
E15. The method according to Embodiments E13-E14, further comprising forming a second dielectric layer on a surface of a second semiconductor substrate; forming a second barrier layer on a surface of the second dielectric layer; forming a second bonding layer on a surface of the second barrier layer; and contacting a surface of the first bonding layer with a surface of the second bonding layer under conditions sufficient to bond the first bonding layer to the second bonding layer;
   wherein the second bonding layer has a higher water diffusivity than the second barrier layer; and
   wherein a thickness of the second bonding layer is less than or equal to about 100 nm;
   wherein the conditions sufficient to bond the first bonding layer to the second bonding layer comprise annealing at a temperature from about 300° C. to about 400° C. for a period of time greater than or equal to about 30 min.
E16. The method according to Embodiments E13-E15, wherein the first dielectric layer, the first barrier layer and the first bonding layer are formed next to a first metal layer disposed on a surface of the substrate, such that an upper surface of the first metal layer and an upper surface of the first bonding layer form a first hybrid bonding surface;
   wherein the second dielectric layer, the second barrier layer and the second bonding layer are formed next to a second metal layer disposed on a surface of the second substrate such that an upper surface of the second metal layer and an upper surface of the second bonding layer form a second hybrid bonding surface; and contacting the first hybrid bonding surface with the second hybrid bonding surface under conditions sufficient to bond the first bonding layer to the second bonding layer, wherein the conditions sufficient to bond the first bonding layer to the second bonding layer comprise annealing at a temperature from about 300° C. to about 400° C. for a period of time greater than or equal to about 30 min.
E17. The method according to Embodiments E13-E16, wherein each bonding layer individually comprises a silicon oxide, a silicon nitride, a silicon oxynitride, silicon carbonitride, silicon oxycarbonitride, or a combination thereof; and/or wherein each barrier layer individually comprises an aluminum oxide, a titanium oxide, a hafnium oxide, a tantalum oxide, silicon carbonitride, or a combination thereof.
   E18. A semiconductor device formed according to embodiments E1-E17.
E19. A semiconductor device, comprising:
   a first substrate comprising a first dielectric bonding layer having a lower surface disposed over, and in contact with an upper surface of a first dielectric barrier layer;
   wherein the first dielectric bonding layer has a higher water diffusivity than the first dielectric barrier layer; and
   wherein a thickness of the first dielectric bonding layer is less than or equal to about 100 nm.
E20. The semiconductor device according to Embodiments E18-E19, wherein the first substrate further comprises a first metal layer disposed thereon next to the first dielectric bonding layer.
E21. The semiconductor device according to Embodiments E18-E20, further comprising a second substrate comprising a second dielectric bonding layer having a lower surface disposed over, and in contact with an upper surface of a second dielectric barrier layer;
   wherein an upper surface of the first dielectric bonding layer is bonded to an upper surface of the second dielectric bonding layer;
   wherein the second dielectric bonding layer has a higher water diffusivity than the second dielectric barrier layer; and
   wherein a thickness of the second dielectric bonding layer is less than or equal to about 100 nm.
   wherein a thickness of each bonding layer is less than or equal to about 100 nm.
E22. The semiconductor device according to Embodiments E18-E21, wherein a thickness of each barrier layer is less than or equal to about 100 nm.
E23. The semiconductor device according to Embodiments E18-E22, wherein the first bonding layer is bonded to the second bonding layer with a bond strength of greater than or equal to about 2 J/m².
E24. The semiconductor device according to Embodiments E18-E23, wherein each bonding layer comprises a silicon oxide, a silicon nitride, a silicon oxynitride, silicon carbonitride, silicon oxycarbonitride, or a combination thereof.
E25. The semiconductor device according to Embodiments E18-E24, wherein each barrier layer comprises an aluminum oxide, a titanium dioxide, a hafnium dioxide, a tantalum oxide, silicon carbonitride, or a combination thereof.
E26. The semiconductor device according to Embodiments E18-E25, wherein each bonding layer consists essentially of silicon dioxide.
E27. The semiconductor device according to Embodiments E18-E26, wherein each barrier layer consists essentially of aluminum oxide.

While the foregoing is directed to embodiments of the present disclosure, other and further embodiments of the disclosure may be devised without departing from the basic scope thereof.

1. A method of preparing a first substrate for bonding with a second substrate, comprising:
depositing a first barrier layer of a first dielectric material on a dielectric layer of the first substrate; and
depositing a first bonding layer of a second dielectric material on the first barrier layer;
wherein the second dielectric material has a higher water diffusivity than the first dielectric material.

2. The method of claim 1, wherein a thickness of the first bonding layer is less than or equal to about 100 nm.

3. The method of claim 1, wherein a thickness of the first barrier layer is less than or equal to about 100 nm.

4. The method of claim 1, wherein the second dielectric material comprises a silicon oxide, a silicon nitride, a silicon oxynitride, silicon carbonitride, silicon oxycarbonitride, or a combination thereof.

5. The method of claim 1, wherein the second dielectric material consists essentially of a silicon oxide.

6. The method of claim 1, wherein the first dielectric material comprises an aluminum oxide, a titanium oxide, a hafnium oxide, a tantalum oxide, silicon carbonitride, or a combination thereof.

7. The method of claim 1, wherein the first dielectric material consists essentially of an aluminum oxide.

8. The method of claim 1, further comprising contacting the first bonding layer of the first substrate with a corresponding first bonding layer of the second substrate under conditions sufficient to bond the first bonding layer of the first substrate to the first bonding layer of the second substrate.

9. The method of claim 8, wherein the first bonding layer of the first substrate is bonded to the first bonding layer of the second substrate with a bond strength of greater than or equal to about 2 J/m².

10. The method of claim 8, wherein the conditions sufficient to bond the first bonding layer of the first substrate to the first bonding layer of the second substrate comprise annealing at a temperature from about 300° C. to about 400° C. for a period of time greater than or equal to about 30 min.

11. The method of claim 1, wherein the first barrier layer is deposited next to and in contact with at least one metal layer, and the first bonding layer is deposited on the first barrier layer next to and in contact with the same one or more metal layers, such that an upper surface of the one or more metal layers and an upper surface of the first bonding layer form a hybrid bonding surface.

12. The method of claim 11, further comprising contacting the hybrid bonding surface of the first substrate with a corresponding hybrid bonding surface of a second substrate such that the first bonding layer and the at least one metal layer of the first substrate each contact a corresponding first bonding layer and at least one metal layer of the second substrate under conditions sufficient to bond the first bonding layer of the first substrate to the first bonding layer of the second substrate.

13. A method of forming a semiconductor device, comprising:
forming a first dielectric layer on a surface of a first semiconductor substrate;
forming a first barrier layer on a surface of the first dielectric layer;
forming a first bonding layer on a surface of the first barrier layer;
wherein the first bonding layer has a higher water diffusivity than the first barrier layer; and
wherein a thickness of the first bonding layer is less than or equal to about 100 nm.

14. The method of claim 13, wherein the first dielectric layer, the first barrier layer and the first bonding layer are formed next to a first metal layer disposed on a surface of the substrate, such that an upper surface of the first metal layer and an upper surface of the first bonding layer form a first hybrid bonding surface.

15. The method of claim 13, further comprising forming a second dielectric layer on a surface of a second semiconductor substrate;
forming a second barrier layer on a surface of the second dielectric layer;
forming a second bonding layer on a surface of the second barrier layer; and
contacting a surface of the first bonding layer with a surface of the second bonding layer under conditions sufficient to bond the first bonding layer to the second bonding layer;
wherein the second bonding layer has a higher water diffusivity than the second barrier layer; and
wherein a thickness of the second bonding layer is less than or equal to about 100 nm;
wherein the conditions sufficient to bond the first bonding layer to the second bonding layer comprise annealing at a temperature from about 300° C. to about 400° C. for a period of time greater than or equal to about 30 min.

16. The method of claim 15, wherein the first dielectric layer, the first barrier layer and the first bonding layer are formed next to a first metal layer disposed on a surface of the substrate, such that an upper surface of the first metal layer and an upper surface of the first bonding layer form a first hybrid bonding surface;
wherein the second dielectric layer, the second barrier layer and the second bonding layer are formed next to a second metal layer disposed on a surface of the second substrate such that an upper surface of the second metal layer and an upper surface of the second bonding layer form a second hybrid bonding surface; and
contacting the first hybrid bonding surface with the second hybrid bonding surface under conditions sufficient to bond the first bonding layer to the second bonding layer, wherein the conditions sufficient to bond the first bonding layer to the second bonding layer comprise annealing at a temperature from about 300° C. to about 400° C. for a period of time greater than or equal to about 30 min.

17. The method of claim 13, wherein each bonding layer individually comprises a silicon oxide, a silicon nitride, a silicon oxynitride, silicon carbonitride, silicon oxycarbonitride, or a combination thereof; and/or
wherein each barrier layer individually comprises an aluminum oxide, a titanium oxide, a hafnium oxide, a tantalum oxide, silicon carbonitride, or a combination thereof.

18. A semiconductor device, comprising:
a first substrate comprising a first dielectric bonding layer having a lower surface disposed over, and in contact with an upper surface of a first dielectric barrier layer;
wherein the first dielectric bonding layer has a higher water diffusivity than the first dielectric barrier layer; and
wherein a thickness of the first dielectric bonding layer is less than or equal to about 100 nm.

19. The semiconductor device of claim 18, wherein the first substrate further comprises a first metal layer disposed thereon next to the first dielectric bonding layer.

20. The semiconductor device of claim 18, further comprising a second substrate comprising a second dielectric bonding layer having a lower surface disposed over, and in contact with an upper surface of a second dielectric barrier layer;
wherein an upper surface of the first dielectric bonding layer is bonded to an upper surface of the second dielectric bonding layer;
wherein the second dielectric bonding layer has a higher water diffusivity than the second dielectric barrier layer; and
wherein a thickness of the second dielectric bonding layer is less than or equal to about 100 nm.
